(19) United States
(12) Patent Application Publication
(10) Pub. No.: US 2026/0136984 A1
(43) Pub. Date: May 14, 2026

(54) SEMICONDUCTOR APPARATUS AND METHOD FOR MANUFACTURING SEMICONDUCTOR APPARATUS

(71) Applicant: Mitsubishi Electric Corporation, Tokyo (JP)

(72) Inventors: Yosuke NAKATA, Tokyo (JP); Yuji SATO, Tokyo (JP); Shin UEGAKI, Tokyo (JP)

(73) Assignee: Mitsubishi Electric Corporation, Tokyo (JP)

(21) Appl. No.: 19/266,873

(22) Filed: Jul. 11, 2025

(30) Foreign Application Priority Data
Nov. 11, 2024 (JP) 2024-196911

(51) Int. Cl. H01L 23/31; H01L 23/00; H01L 23/492; H01L 23/495

(52) U.S. Cl. CPC H10W 74/111; H10W 42/121; H10W 70/20; H10W 90/811

(57) ABSTRACT

An object of the present disclosure is to provide a technique that can uniformly bond a conductor plate covered with a sealing material and a metal plate. According to the present disclosure, a semiconductor apparatus comprises a conductor plate that has a first main surface and a second main surface which are opposed to each other, a semiconductor device that is bonded to the first main surface of the conductor plate, a sealing material that covers a part of the first main surface of the conductor plate and the semiconductor device, and a metal plate that is bonded to the second main surface of the conductor plate. The first main surface of the conductor plate has a pressing portion as a region exposed from the sealing material.

### BACKGROUND OF THE INVENTION

### Field

The present disclosure relates to a semiconductor apparatus and a method for manufacturing a semiconductor apparatus.

### Background

Japanese Unexamined Patent Application Publication No. 2024-20691 discloses a technology for soldering a conductor plate with a semiconductor device mounted thereon to an insulating substrate with a circuit pattern. However, when the conductor plate and the insulating substrate were joined by soldering, there was a problem that cracks occurred in the solder joint due to stress from cycle tests and the like.

To solve this problem, there is a method of adopting sintering bonding or solid-phase bonding, which have superior bonding longevity compared to solder bonding. These sintering bonding and solid-phase bonding require a pressure bonding process in a high-temperature environment of around 300 degrees.

However, when applying the above-mentioned method to the bonding of a conductor plate covered with a sealing material and a metal plate, the sealing material softens in the high-temperature environment during the pressure bonding process. As a result, there was a problem that uniform bonding is difficult to achieve due to cracking or deformation of the sealing material around the pressurized area.

### SUMMARY

In view of the above-described problems, an object of the present disclosure is to provide a semiconductor apparatus and a method for manufacturing the semiconductor apparatus that can uniformly bond a conductor plate covered with a sealing material and a metal plate by applying pressure to a part of the conductor plate exposed from the sealing material, thereby solving the above-described problem.

The features and advantages of the present disclosure may be summarized as follows.

A semiconductor apparatus according to the present disclosure includes: a conductor plate that has a first main surface and a second main surface which are opposed to each other; a semiconductor device that is bonded to the first main surface of the conductor plate; a sealing material that covers a part of the first main surface of the conductor plate and the semiconductor device; and a metal plate that is bonded to the second main surface of the conductor plate, wherein the first main surface of the conductor plate has a pressing portion as a region exposed from the sealing material.

Other and further objects, features and advantages of the disclosure will appear more fully from the following description.

### BRIEF DESCRIPTION OF DRAWINGS

FIG. 1 is a plan view showing a semiconductor apparatus according to the first embodiment of the present disclosure.

FIG. 2 is a first diagram showing a sealing process of the semiconductor apparatus according to the first embodiment of the present disclosure.

FIG. 3 is a second diagram showing the sealing process of the semiconductor apparatus according to the first embodiment of the present disclosure.

FIG. 4 is a third diagram showing the sealing process of the semiconductor apparatus according to the first embodiment of the present disclosure.

FIG. 5 is a fourth diagram showing the sealing process of the semiconductor apparatus according to the first embodiment of the present disclosure.

FIG. 6 is a plan view showing a semiconductor apparatus according to the second embodiment of the present disclosure.

FIG. 7 is a diagram showing thermal interference in a semiconductor apparatus according to a comparative example.

FIG. 8 is a diagram showing thermal interference in the semiconductor apparatus according to the second embodiment of the present disclosure.

FIG. 9 is a first diagram showing a sealing process of the semiconductor apparatus according to the second embodiment of the present disclosure.

FIG. 10 is a second diagram showing the sealing process of the semiconductor apparatus according to the second embodiment of the present disclosure.

FIG. 11 is a third diagram showing the sealing process of the semiconductor apparatus according to the second embodiment of the present disclosure.

FIG. 12 is a fourth diagram showing the sealing process of the semiconductor apparatus according to the second embodiment of the present disclosure.

FIG. 13 is a plan view showing a semiconductor apparatus according to the third embodiment of the present disclosure.

FIG. 14 is a cross-sectional view taken along line A-A′ in FIG. 13.

FIG. 15 is a cross-sectional view taken along line B-B′ in FIG. 13.

### DESCRIPTION OF EMBODIMENTS

Semiconductor apparatuses of the present disclosure will be described with reference to the drawings. The same or corresponding components may be given the same reference numerals, and repetitive descriptions may be omitted. In the present disclosure, a surface opposing the first main surface is referred to as the second main surface.

### First Embodiment

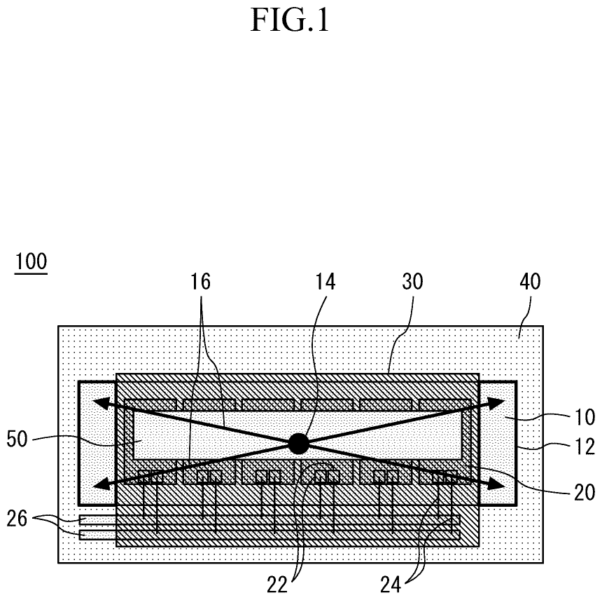

FIG. 1 is a plan view showing a semiconductor apparatus according to the first embodiment of the present disclosure. The semiconductor apparatus 100 comprises a conductor plate 10. The conductor plate 10 is made of a material primarily composed of copper, for example.

Multiple semiconductor devices 20 are bonded to the first main surface of the conductor plate 10 by a connecting material. This connecting material is, for example, a sintered bonding material, and is made of a material primarily comprising silver or copper.

The semiconductor device 20 is, for example, a switching element such as a MOSFET. When the semiconductor device 20 is a MOSFET, the conductor plate 10 can be used as a drain electrode. Furthermore, when the semiconductor device 20 is a MOSFET, a control pad 22 is provided on the semiconductor device 20. The control pad 22 is, for example, a gate pad or a Kelvin source pad. The control pad 22 is electrically connected to a signal terminal 26 using a wire 24 made of, for example, aluminum, copper, or silver.

The semiconductor device 20 is made of a heat-resistant material. The heat-resistant material is, for example, silicon carbide. When the semiconductor device 20 is made of silicon carbide, the current capacity per semiconductor device 20 becomes small. Therefore, to ensure the output capacity of the semiconductor apparatus 100, multiple semiconductor devices 20 are often mounted on the conductor plate 10.

Furthermore, an electrode material 50 is connected to the first main surface of the semiconductor device 20 by a bonding material. The electrode material 50 is, for example, made of copper. This bonding material is, for example, a sintered bonding material and is made of a material primarily consisting of, for example, silver or copper.

When multiple semiconductor devices 20 are mounted on the conductor plate 10, the electrode material is configured to electrically connect the first main surfaces of the multiple semiconductor devices 20. Therefore, when the semiconductor devices 20 are MOSFETs, the electrode material can be used as a source electrode.

The semiconductor device 20 and the electrode material 50 are bonded, for example, by sintered bonding. The sintered bonding between the semiconductor device 20 and the electrode material 50 does not require a process involving pressurization in a high-temperature environment for two reasons. The first reason is that the connection area between the electrode material 50 and the first main surface of the semiconductor device 20 is smaller than the connection area between the conductor plate 10 and the second main surface of the semiconductor device 20. The second reason is that the heat dissipation properties of the semiconductor device 20 are determined depending on the state of the second main surface of the semiconductor device 20. Due to these two reasons, there is little need to consider thickness uniformity and density in the bonding between the semiconductor device 20 and the electrode material 50. Therefore, for the sintered bonding between the semiconductor device 20 and the electrode material 50, it is preferable to adopt a process that does not involve pressurization in a high-temperature environment.

The conductor plate 10 and the semiconductor device 20 are bonded, for example, by sintered bonding. A process that does not involve pressurization under high-temperature conditions may be adopted for the sintered bonding of the conductor plate 10 and the semiconductor device 20. For instance, when the semiconductor device 20 is a MOSFET made of silicon carbide, its thickness is typically 10 mm or less. Such a semiconductor device 20 exhibits minimal warpage changes during temperature rise and fall. Therefore, in the sintered bonding of such a semiconductor device 20 and the conductor plate 10, even when adopting a process that does not involve pressurization, a uniform bond can be easily obtained.

On the other hand, a process involving pressurization may be adopted for the sintered bonding between the conductor plate 10 and the semiconductor device 20. The semiconductor device 20 is made of a heat-resistant material and has a thickness of 100 μm or less, which is thin. Therefore, by using a buffer material during pressurization, the conductor plate 10 and the semiconductor device 20 can be bonded well. In other words, even when adopting a process involving pressurization in such sintered bonding between the semiconductor device 20 and the conductor plate 10, a uniform bond can be easily obtained.

A portion of the first main surface of the conductor plate 10 and the first main surface of the semiconductor device 20 are covered with the sealing material 30. The sealing material 30 is made of, for example, an epoxy resin-based material. The regions exposed from the sealing material 30 at both ends of the first main surface of the conductor plate 10 are referred to as pressing portions 12. In other words, the pressing portions 12 according to the present embodiment include regions containing two opposing edges of the first main surface of the conductor plate 10.

In the present embodiment, multiple pressing portions 12 are arranged on multiple straight lines 16 passing through the center of gravity 14 of the conductor plate 10. For example, the multiple pressing portions 12 are configured to include a set of pressing portions where a straight line connecting a particular pressing portion 12 with other pressing portions 12 passes through the center of gravity 14 of the conductor plate 10. The sealing process of the semiconductor apparatus 100 using the sealing material 30 will be described later.

A metal plate 40 is bonded to the second main surface side of the conductor plate 10. The sealing material 30 is provided so as to cover a portion of the first main surface of the conductor plate 10, the first main surface of the semiconductor device 20, the first main surface of the control pad 22, the wire 24, and a portion of the first main surface of the signal terminal 26. In other words, the sealing material 30 is connected to the metal plate 40.

The metal plate 40 is, for example, a part of a circuit pattern formed on an insulating substrate. The insulating substrate is, for example, a ceramic substrate such as silicon nitride. The insulating substrate is used to form a higher-level semiconductor apparatus by using multiple substrates. The circuit pattern is made of a material primarily composed of copper, for example.

The conductor plate 10 has a connection pattern on a surface facing the circuit pattern with an insulating substrate interposed therebetween. The connection pattern is made of a material primarily consisting of copper, for example.

The connection pattern is a pattern for connecting to a cooler. The cooler is installed to cool an upper semiconductor apparatus and is made of a material primarily composed of copper or aluminum, for example. The cooler may be equipped with multiple pin-fin protrusions and cooled by cooling water. Alternatively, the cooler may be equipped with multiple blade-like protrusions and air-cooled by blowing air between the blades.

The cooler and the insulating substrate are connected, for example, via a case. The case is installed, for example, on top of the cooler to surround the periphery of the insulating substrate. The interior of the case is filled with a sealing material, such as gel. Furthermore, case electrodes are provided on the case. The case electrodes are electrically connected to corresponding circuit patterns on the insulating substrate. An inverter unit is formed by connecting, for example, output terminals and capacitor terminals to the case electrodes.

The connection between the connection pattern and the cooler is performed, for example, by soldering. The connection pattern is larger compared to the circuit pattern. Additionally, the connection pattern is far from the semiconductor device 20, which is the heat source of the semiconductor apparatus 100, and close to the cooler. Furthermore, the connection pattern is connected to the circuit pattern via the conductor plate 10 under the semiconductor device 20, making it less susceptible to temperature rise due to heat diffusion and resulting in a gentler temperature gradient. For these reasons, there is a low necessity to use sintered bonding for the connection between the connection pattern and the cooler.

Furthermore, when bonding the connection pattern and the cooler by sintered bonding, the warpage of the cooler and the insulating substrate changes due to temperature variations occurring during the connection process. As a result, it becomes difficult to apply sintered bonding. Therefore, by performing the connection between the connection pattern and the cooler using solder bonding, a sufficient power cycle lifetime is ensured.

The conductor plate 10 and the metal plate 40 are bonded by a joining method involving pressurization. The joining method involving pressurization is, for example, sintering bonding or solid-phase bonding. When the joining method involving pressurization is sintering bonding, the conductor plate 10 and the metal plate 40 are bonded with a sintered bonding material. The sintered bonding material is, for example, a material primarily composed of silver or copper. The sintering bonding process includes, for example, a step of printing silver paste, a step of drying the printed silver paste, and a step of sintering bonding.

On the other hand, when the joining method involving pressurization is solid-phase bonding, the conductor plate 10 and the metal plate 40 are bonded with a solid-phase bonding material. The solid-phase bonding material is, for example, a material primarily composed of silver or copper.

The bonding of the conductor plate 10 and the metal plate 40 is performed under a specific high-temperature environment exceeding the glass transition temperature of the sealing material 30. The glass transition temperature of the sealing material 30 is, for example, 200 degrees. The specific high temperature is, for example, 300 degrees.

The pressure used in bonding the conductor plate 10 and the metal plate 40 is applied by pressing the pressing portion 12. The pressure applied during pressing needs to be optimized according to the type of sintering bonding material or solid-phase bonding material used, or the process employed. The pressure is, for example, in the range of several MPa to several tens of MPa.

Prior to explaining the benefits obtained by bonding the conductor plate 10 and the metal plate 40 according to the present embodiment, the issues arising in bonding a conductor plate and a metal plate in a comparative example will be described in detail. Patent Document 1 discloses a technology for soldering a conductor plate with a semiconductor device mounted thereon to an insulating substrate with a circuit pattern.

However, when the conductor plate and the insulating substrate were bonded by soldering, there was a problem that cracks occurred in the solder joint due to stress from cycle tests and the like. When cracks form in the solder joint, the thermal conductivity of the solder joint decreases, resulting in an increase in thermal resistance between the semiconductor device and the cooler. As a result, this led to a problem of decreased power cycle life due to an increase in the maximum temperature of the semiconductor device during power cycle testing.

To address the aforementioned issue, there is a method of adopting sintered bonding or solid-phase bonding, which have superior bonding lifetimes compared to solder bonding. However, when bonding a conductor plate sized to accommodate multiple semiconductor devices using sintered bonding or solid-phase bonding, a pressure bonding process in a high-temperature environment of approximately 300 degrees is required.

On the other hand, in a sintering bonding process where simple semiconductor devices are directly connected to circuit patterns and the like, it is possible to use a process without applying pressure since the warpage change of the semiconductor devices under high-temperature environments is small. In contrast, consider the case of sintering bonding between a complex structured conductor plate, on which multiple semiconductor devices are mounted, internal wiring is routed, and the upper surface is covered with encapsulant, and circuit patterns. In this case, warpage occurs in the conductor plate, and the warpage shape changes with the temperature rise during sintering bonding. Therefore, it becomes necessary to control the shape change by applying pressure to the conductor plate while bonding.

However, for a conductor plate covered with a sealing material on its upper surface, it is necessary to apply pressure to the conductor plate through the sealing material. Here, the sealing material commonly used in semiconductor apparatuses has a glass transition temperature of around 200 degrees. Therefore, in the aforementioned bonding process, the pressurized sealing material becomes more susceptible to softening as its properties change under a high-temperature environment exceeding the glass transition temperature. As a result, the resin strength or delamination resistance of the sealing material changes. Consequently, issues arose such as cracking or deformation of the sealing material around the pressurized area, delamination at the interface between the conductor plate and the sealing material, or difficulty in achieving uniform bonding due to the pressure not being evenly transmitted to the conductor plate.

The benefits obtained by bonding the conductor plate 10 and the metal plate 40 according to the present embodiment will be explained. As a comparative example, consider a case where a conductor plate and a metal plate, both entirely covered with sealing material, are bonded using a joining method involving pressurization.

In this case, the pressurization for bonding the conductor plate and the metal plate is applied by pressing the sealing material covering the conductor plate. This pressing is performed in a high-temperature environment exceeding the glass transition temperature of the sealing material covering the conductor plate. As a result, the sealing material covering the conductor plate deforms, peels off from the conductor plate or the semiconductor device, or cracks. In other words, the sealing material deteriorates. Therefore, the joining method according to the comparative example had a problem of decreased manufacturability or reliability of the resulting semiconductor apparatus.

On the other hand, in the present embodiment, the pressurization for bonding the conductor plate 10 and the metal plate 40 is performed by pressing the pressing portion 12. Specifically, by applying a load to the pressing portion 12 to bond the conductor plate 10 and the metal plate 40 under pressure, pressurization to the sealing material 30 can be avoided. As a result, degradation of the sealing material 30 can be prevented, enabling uniform bonding of the conductor plate 10 covered with the sealing material 30 and the metal plate 40.

Furthermore, the plurality of pressing portions 12 according to the present embodiment are arranged on a plurality of straight lines 16 passing through the center of gravity 14 of the conductor plate 10. In other words, when the plurality of pressing portions 12 are pressed, a load is uniformly applied to the entire conductor plate 10. As a result, the conductor plate 10 covered with the sealing material 30 and the metal plate 40 can be more uniformly bonded.

While the embodiment described herein shows the conductor plate 10 and the metal plate 40 being bonded by sintering bonding or solid-phase bonding, the present disclosure is not limited to these methods. In other words, for bonding the conductor plate 10 and the metal plate 40, a highly reliable joining method involving heating and pressurization may be selected.

Furthermore, in the bonding according to the present embodiment, since the conductor plate 10 and the metal plate 40 can be uniformly bonded, the benefit of improving yield and productivity can also be obtained.

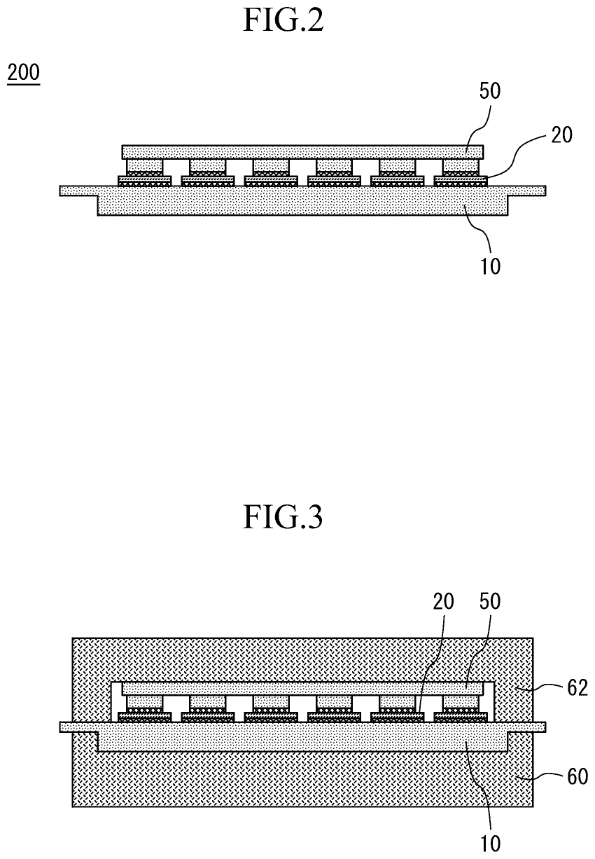

A specific example of the sealing process for the semiconductor apparatus 100 will be explained. FIG. 2 is a first diagram showing a sealing process of the semiconductor apparatus according to the first embodiment of the present disclosure. FIG. 2 shows an example of the structure of the bonded body 200, which is the state of the semiconductor apparatus 100 before sealing. The bonded body 200 comprises a conductor plate 10. A semiconductor device 20 is bonded on the conductor plate 10, and an electrode material 50 is bonded on the semiconductor device 20.

FIG. 3 is a second diagram showing the sealing process of the semiconductor apparatus according to the first embodiment of the present disclosure. FIG. 3 shows the state in which the bonded body 200 is incorporated into a molding die in order to seal the bonded body 200.

The molding die consists of a lower die 60 that supports the second main surface side of the conductor plate 10, and an upper die 62 that contacts the first main surface side of the conductor plate 10 with protrusions. The region where these protrusions contact the conductor plate 10 becomes the pressing portion 12.

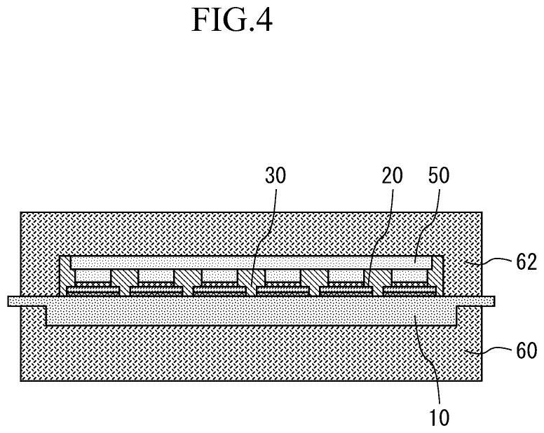

FIG. 4 is a third diagram showing the sealing process of the semiconductor apparatus according to the first embodiment of the present disclosure. FIG. 4 illustrates a state where the bonded body 200 is encapsulated by filling the sealing material 30 into a molding die. The sealing material 30 is made of, for example, epoxy resin. This filling is performed, for example, by a transfer molding technique.

Furthermore, the filling shown in FIG. 4 may be performed with a buffer film additionally interposed between the lower die 60 and the conductor plate 10, and between the upper die 62 and the conductor plate 10. This configuration can prevent epoxy resin from adhering to areas of the conductor plate 10 surface other than the region where the sealing material 30 is in contact.

Alternatively, after completing the filling as shown in FIG. 4, the epoxy resin adhering to regions other than where the sealing material 30 contacts on the surface of the conductor plate 10 may be removed to expose the surface of the conductor plate 10. This configuration allows limiting the region where epoxy resin adheres on the surface of the conductor plate 10 to only the area where the sealing material 30 makes contact.

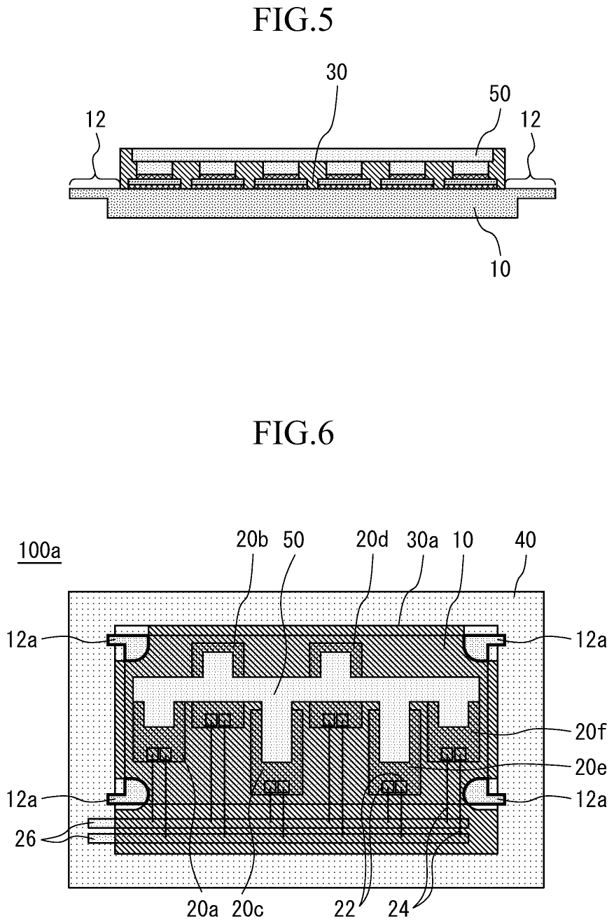

FIG. 5 is a fourth diagram showing the sealing process of the semiconductor apparatus according to the first embodiment of the present disclosure. Through the processes shown in FIGS. 2 to 4, pressing portions 12, which are areas exposed from the sealing material 30, are formed at both ends of the first main surface of the conductor plate 10.

The pressing portion 12 may be provided in multiple instances. In the present embodiment, the pressing portion 12 comprises two areas exposed from the sealing material 30 at both ends of the first main surface of the conductor plate 10. The two pressing portions 12 are configured to be arranged on multiple lines passing through the center of gravity 14 of the conductor plate 10.

Similarly to the pressing portion 12 being exposed from the sealing material 30, the signal terminals 26 and the electrode material 50 are also exposed at necessary locations according to their intended use. The signal terminals 26 become usable as terminals by being exposed and extending from one side surface of the sealing material 30. The electrode material 50 becomes usable as an electrode by being exposed from the upper surface of the sealing material.

### Second Embodiment

FIG. 6 is a plan view showing a semiconductor apparatus according to the second embodiment of the present disclosure. The semiconductor apparatus 100a of the present embodiment differs from the semiconductor apparatus 100 in that the pressing portion 12a is an area exposed from a notched portion of the sealing material 30a, and that multiple semiconductor devices are arranged in a zigzag pattern.

The semiconductor apparatus 100a comprises a sealing material 30a. The sealing material 30a has four notched portions when viewed in plan view. In this embodiment, the pressing portion 12a includes regions containing four corner portions of the first main surface of the conductor plate 10, which are exposed from these notched portions. Furthermore, in this embodiment, multiple pressing portions 12a are exposed in such a manner that they can be connected by multiple lines passing through the center of gravity of the conductor plate 10.

The semiconductor apparatus 100a also includes semiconductor devices 20a to 20f. The semiconductor devices 20a to 20f are arranged in a zigzag pattern along the longitudinal direction of the first main surface of the conductor plate 10, such that their respective heat generation centers are not aligned in a straight line. Furthermore, the semiconductor devices 20a and 20f, which are positioned at both ends, are arranged closer to the center of the first main surface in the short-side direction compared to one or more of the other semiconductor devices 20b to 20e. As a result, the aforementioned notched portions of the sealing material 30a are provided in very close proximity to the semiconductor devices 20a and 20f.

The benefits obtained by bonding the conductor plate 10 and the metal plate 40 according to the present embodiment will be explained. The pressing portion 12a according to the present embodiment is a region including the four corner areas of the first main surface of the conductor plate 10. Therefore, the semiconductor apparatus 100a can reduce its longitudinal dimension compared to the semiconductor apparatus 100, which has a pressing portion 12 that includes a region comprising two opposing sides of the first main surface of the conductor plate 10. In other words, the semiconductor apparatus 100a can be miniaturized in overall size compared to the semiconductor apparatus 100.

Furthermore, the semiconductor devices 20a to 20f of the present embodiment are arranged in a zigzag pattern so that their respective heat generation centers are not aligned in a straight line. This arrangement can suppress thermal interference caused by the semiconductor devices.

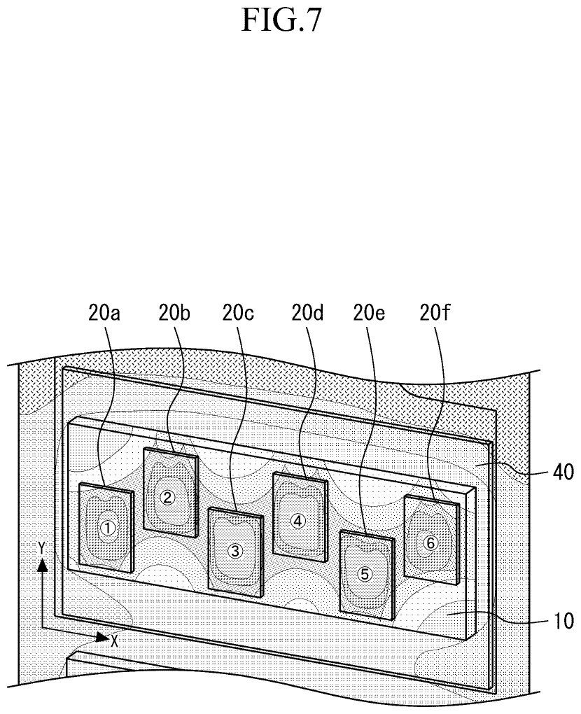

The thermal interference caused by semiconductor devices will be explained in more detail. FIG. 7 is a diagram showing thermal interference in a semiconductor apparatus according to a comparative example.

In FIG. 7, semiconductor devices 20a and 20f are not positioned closer to the center of the first main surface in the short-side direction of the first main surface compared to the other semiconductor devices, namely semiconductor devices 20b to 20e. In other words, semiconductor devices 20a and 20f are arranged in the vicinity of one of the four corner portions of the first main surface of the conductor plate 10. As a result, semiconductor devices 20a and 20f can more easily dissipate heat to the outside of the conductor plate 10. Therefore, the thermal interference of semiconductor devices 20b to 20e becomes relatively larger than that of semiconductor devices 20a and 20f. In other words, semiconductor devices 20b to 20e, which are not positioned at both ends, are more likely to become hotter than semiconductor devices 20a and 20f, which are positioned at both ends.

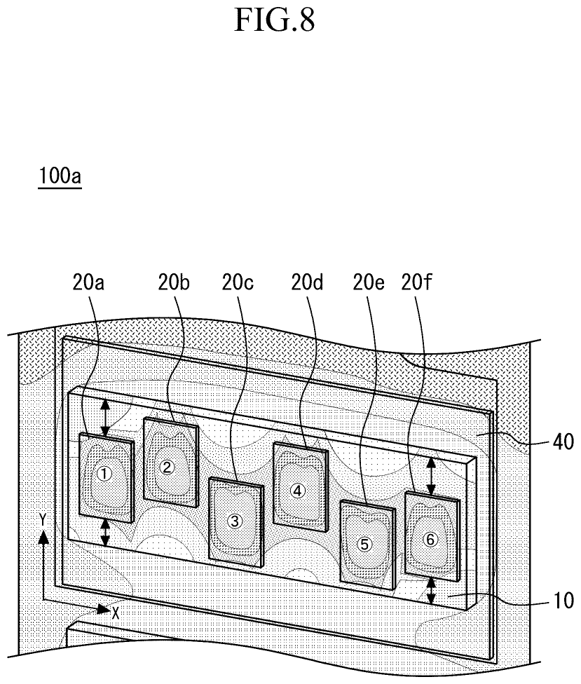

FIG. 8 is a diagram showing thermal interference in the semiconductor apparatus according to the second embodiment of the present disclosure. In FIG. 8, semiconductor devices 20a and 20f are positioned closer to the center of the first main surface in the short-side direction of the first main surface compared to the other semiconductor devices 20b to 20e. As a result, it becomes more difficult for semiconductor devices 20a and 20f to dissipate heat to the outside of the conductor plate 10. Therefore, the thermal interference of semiconductor devices 20a and 20f in FIG. 8 becomes relatively larger than the thermal interference of semiconductor devices 20a and 20f in FIG. 7. In other words, the semiconductor devices 20a and 20f positioned at both ends become as hot as the semiconductor devices 20b to 20e that are not positioned at both ends.

As described above, in the plurality of semiconductor devices according to the present embodiment, the semiconductor devices disposed at both ends are positioned closer to the center of the first main surface in the short-side direction of the first main surface, compared to one or more of the other semiconductor devices. This arrangement enables the temperature of the plurality of semiconductor devices to be uniformized.

Furthermore, the pressing portion 12a according to the present embodiment is disposed in an area created by arranging the semiconductor devices, which are placed at both ends, closer to the center of the first main surface in the short-side direction of the first main surface. In other words, there is no need to provide a new area for the pressing portion 12a. Therefore, the semiconductor apparatus according to the present embodiment can be miniaturized in overall size compared to the semiconductor apparatus of the first embodiment.

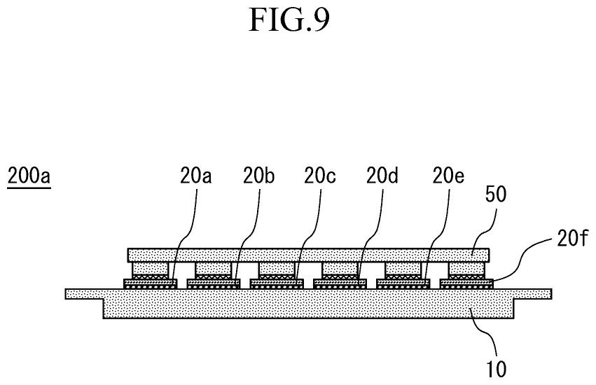

A specific example of the sealing process for the semiconductor apparatus 100a will be explained. FIG. 9 is a first diagram showing a sealing process of the semiconductor apparatus according to the second embodiment of the present disclosure. FIG. 9 shows an example of the configuration of the bonded body 200a, which is the state of the semiconductor apparatus 100a before sealing. The bonded body 200a includes a conductor plate 10. Semiconductor devices 20a to 20f are bonded on the conductor plate 10, and electrode materials 50 are bonded on top of the semiconductor devices 20a to 20f.

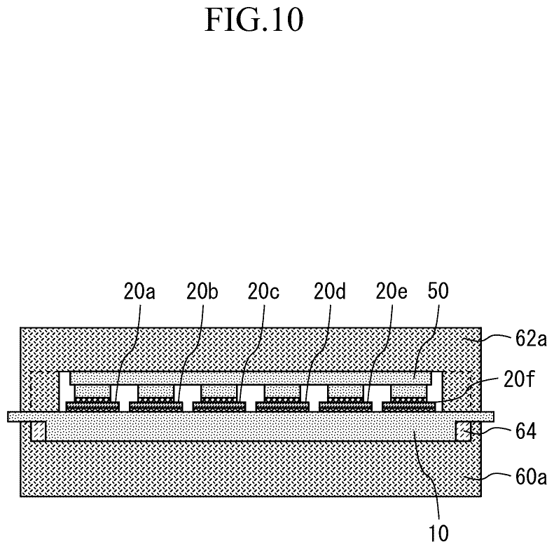

FIG. 10 is a second diagram showing the sealing process of the semiconductor apparatus according to the second embodiment of the present disclosure. FIG. 10 shows the state where the bonded body 200a is incorporated into a molding die for resin molding in order to seal the bonded body 200a.

The molding die comprises a lower die 60a supporting the second main surface side of the conductor plate 10, and an upper die 62a contacting the first main surface side of the conductor plate 10 with protrusions. These protrusions are configured to manufacture the cut-out portions of the sealing material 30a shown in FIG. 6. In other words, the area where these protrusions contact the conductor plate 10 becomes the pressing portion 12a.

Furthermore, in the present embodiment, a lower frame 64 is provided for the upper die 62a. The lower frame 64 is made of a material primarily consisting of resin, for example.

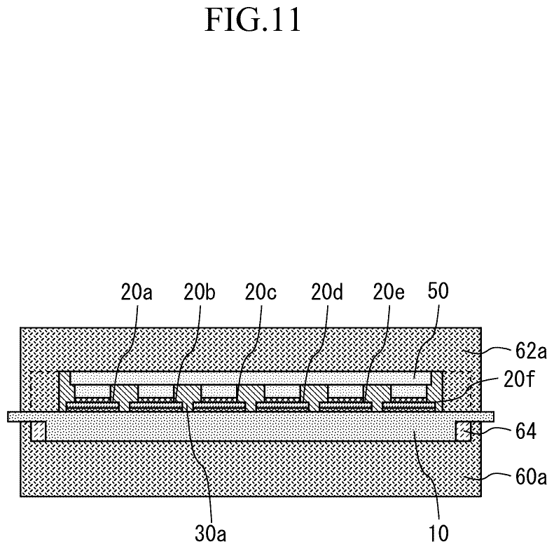

FIG. 11 is a third diagram showing the sealing process of the semiconductor apparatus according to the second embodiment of the present disclosure. FIG. 11 shows a state in which the bonded body 200a is sealed by filling a sealing material 30a into a molding die. The sealing material 30a is made of, for example, epoxy resin. This filling is performed, for example, by a transfer molding sealing technique.

Furthermore, the filling shown in FIG. 11 may be performed with buffer films additionally interposed between the lower die 60a and the conductor plate 10, and between the upper die 62a and the conductor plate 10. This configuration can prevent epoxy resin from adhering to areas of the conductor plate 10 surface other than the regions where the sealing material 30a comes into contact.

Alternatively, after completing the filling as shown in FIG. 11, the epoxy resin adhered to areas other than the region where the sealing material 30a contacts on the surface of the conductor plate 10 may be removed to expose the surface of the conductor plate 10. This configuration allows limiting the region where epoxy resin adheres on the surface of the conductor plate 10 to only the area where the sealing material 30a makes contact.

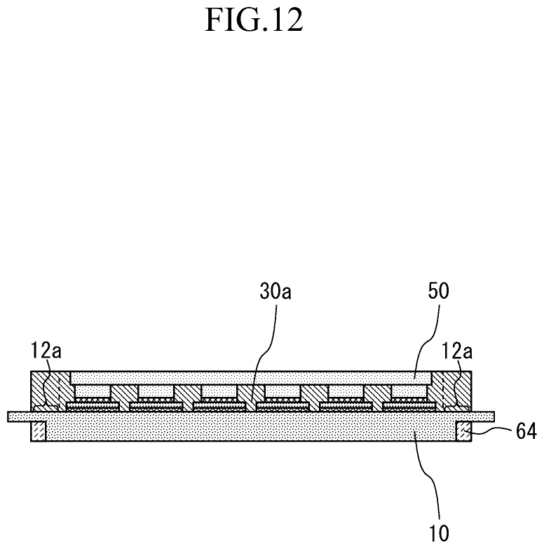

FIG. 12 is a fourth diagram showing the sealing process of the semiconductor apparatus according to the second embodiment of the present disclosure. Through the processes shown in FIGS. 9 to 11, pressing portions 12a, which are regions exposed from the sealing material 30a, are formed at both ends of the first main surface of the conductor plate 10.

The pressing portion 12a may be provided in plurality. The pressing portion 12a according to the present embodiment is an area including four corner regions of the first main surface of the conductor plate 10, which are exposed by notched portions of the sealing material 30. Furthermore, in the present embodiment, multiple pressing portions 12a are exposed in such a way that they can be connected by multiple lines passing through the center of gravity of the conductor plate 10.

Similarly to the pressing portion 12a being exposed from the sealing material 30a, the signal terminals 26 and the electrode material 50 are also exposed at necessary locations depending on the application. The signal terminals 26 are exposed and extend from one side surface of the sealing material 30, thereby becoming usable as terminals. The electrode material 50 is exposed from the upper surface of the sealing material, thereby becoming usable as an electrode.

### Third Embodiment

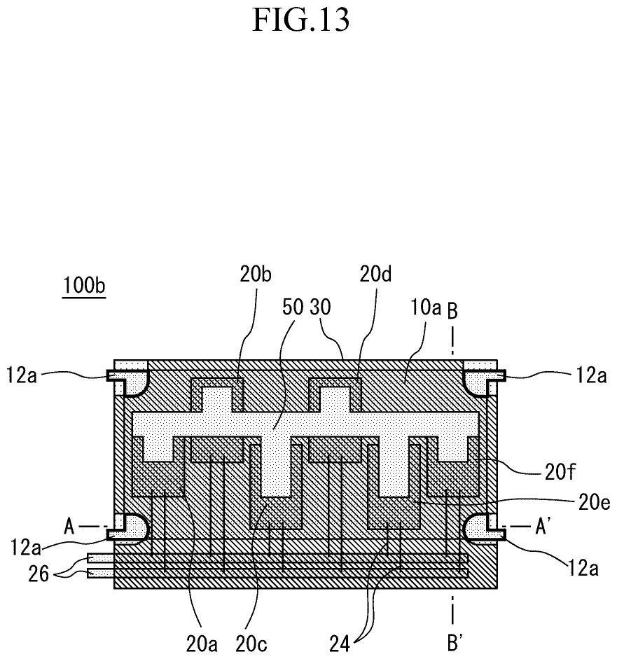

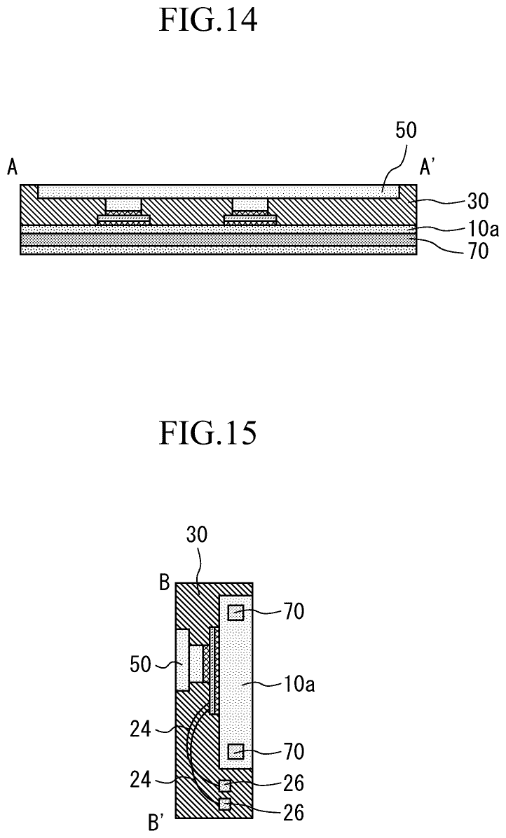

FIG. 13 is a plan view showing a semiconductor apparatus according to the third embodiment of the present disclosure. FIG. 14 is a cross-sectional view taken along line A-A′ in FIG. 13. FIG. 15 is a cross-sectional view taken along line B-B′ in FIG. 13. The semiconductor apparatus 100b of the present embodiment differs from the semiconductor apparatus 100a in that a bridging material 70 is provided inside the conductor plate 10a.

The semiconductor apparatus 100b comprises a conductor plate 10a. The conductor plate 10a contains a bridging material 70 inside. The bridging material 70 is, for example, made of a material that has a higher hardness and a lower thermal diffusion coefficient than the conductor plate 10a. The bridging material 70 may be, for example, a single metal or metal alloy, or it may be an insulating material such as ceramic.

The bridging material 70 extends in the longitudinal direction of the conductor plate 10a. The bridging material 70 is disposed directly beneath the pressing portion 12a. Furthermore, the bridging material 70 is positioned in a location that is not directly beneath the semiconductor devices 20a to 20f.

By placing the bridging material 70 directly beneath the pressing portion 12a, the load applied to the pressing portion 12a can be transmitted more uniformly to the entire conductor plate 10a. It should be noted that when a material with high hardness is used for the bridging material 70, the thermal diffusion coefficient often becomes low. However, in the present embodiment, since the bridging material 70 is placed in a position not directly beneath the semiconductor devices 20a to 20f, a decrease in the heat dissipation properties of the semiconductor devices can be avoided.

As described above, the semiconductor apparatus 100b according to the present embodiment includes a bridging material 70 inside the conductor plate 10a. As a result, the semiconductor apparatus 100b can transmit the load related to the pressing portion 12a more uniformly through the entire conductor plate 10a.

Hereinafter, various aspects of the present disclosure will be collectively described as appendixes.

### (Appendix 1)

A semiconductor apparatus comprising:
a conductor plate that has a first main surface and a second main surface which are opposed to each other;
a semiconductor device that is bonded to the first main surface of the conductor plate;
a sealing material that covers a part of the first main surface of the conductor plate and the semiconductor device; and
a metal plate that is bonded to the second main surface of the conductor plate, wherein
the first main surface of the conductor plate has a pressing portion as a region exposed from the sealing material.

### (Appendix 2)

The semiconductor apparatus according to appendix 1, wherein
the conductor plate and the metal plate are bonded together by a sintering bonding material or a solid-phase bonding material.

### (Appendix 3)

The semiconductor apparatus according to appendix 1 or 2, wherein
the pressing portion is provided as a plurality of pressing portions which are arranged on a plurality of straight lines passing through the center of gravity of the conductor plate.

### (Appendix 4)

The semiconductor apparatus according to any one of appendixes 1 to 3, wherein
the sealing material has a notch portion, and the pressing portion is exposed from the notch portion.

### (Appendix 5)

The semiconductor apparatus according to appendix 4, wherein
the semiconductor device includes a plurality of semiconductor devices,
the plurality of semiconductor devices are arranged in a zigzag manner in a longitudinal direction of the first main surface of the conductor plate such that respective heat generation centers are not aligned on a straight line,
the semiconductor devices which are arranged at both ends of the plurality of semiconductor devices are arranged close to a center of the first main surface in a transverse direction of the first main surface compared to one or more semiconductor devices among the other semiconductor devices, and
the notch portion is provided in a vicinity of each of the semiconductor devices which are arranged at both ends of the plurality of semiconductor devices.

### (Appendix 6)

The semiconductor apparatus according to any one of appendixes 1 to 5, further comprising
a bridging material that is provided in an internal portion of the conductor plate and is formed of a material with higher hardness than the conductor plate, wherein
the bridging material spreads in a longitudinal direction of the conductor plate and is arranged directly below the pressing portion.

### (Appendix 7)

The semiconductor apparatus according to appendix 6, wherein
the bridging material is formed of a material with a lower thermal diffusion coefficient than the conductor plate and is arranged in a position which is not directly below the semiconductor device.

### (Appendix 8)

A method for manufacturing the semiconductor apparatus according to any one of appendixes 1 to 7, the method comprising
a sealing step using a die, wherein
the die includes an upper die which comes into contact with the conductor plate from an upper surface of the conductor plate, and
the upper die has a protrusion which contacts with the pressing portion.

Obviously many modifications and variations of the present disclosure are possible in the light of the above teachings. It is therefore to be understood that within the scope of the appended claims the invention may be practiced otherwise than as specifically described.

The entire disclosure of a Japanese Patent Application No. 2024-196911, filed on Nov. 11, 2022 including specification, claims, drawings and summary, on which the Convention priority of the present application is based, is incorporated herein by reference in its entirety.

1. A semiconductor apparatus comprising:
a conductor plate that has a first main surface and a second main surface which are opposed to each other;
a semiconductor device that is bonded to the first main surface of the conductor plate;
a sealing material that covers a part of the first main surface of the conductor plate and the semiconductor device; and
a metal plate that is bonded to the second main surface of the conductor plate, wherein
the first main surface of the conductor plate has a pressing portion as a region exposed from the sealing material.

2. The semiconductor apparatus according to claim 1, wherein
the conductor plate and the metal plate are bonded together by a sintering bonding material or a solid-phase bonding material.

3. The semiconductor apparatus according to claim 1, wherein
the pressing portion is provided as a plurality of pressing portions which are arranged on a plurality of straight lines passing through the center of gravity of the conductor plate.

4. The semiconductor apparatus according to claim 1, wherein
the sealing material has a notch portion, and
the pressing portion is exposed from the notch portion.

5. The semiconductor apparatus according to claim 4, wherein
the semiconductor device includes a plurality of semiconductor devices,
the plurality of semiconductor devices are arranged in a zigzag manner in a longitudinal direction of the first main surface of the conductor plate such that respective heat generation centers are not aligned on a straight line,
the semiconductor devices which are arranged at both ends of the plurality of semiconductor devices are arranged close to a center of the first main surface in a transverse direction of the first main surface compared to one or more semiconductor devices among the other semiconductor devices, and
the notch portion is provided in a vicinity of each of the semiconductor devices which are arranged at both ends of the plurality of semiconductor devices.

6. The semiconductor apparatus according to claim 1, further comprising
a bridging material that is provided in an internal portion of the conductor plate and is formed of a material with higher hardness than the conductor plate, wherein
the bridging material spreads in a longitudinal direction of the conductor plate and is arranged directly below the pressing portion.

7. The semiconductor apparatus according to claim 6, wherein
the bridging material is formed of a material with a lower thermal diffusion coefficient than the conductor plate and is arranged in a position which is not directly below the semiconductor device.

8. A method for manufacturing the semiconductor apparatus according to claim 1, the method comprising
a sealing step using a die, wherein
the die includes an upper die which comes into contact with the conductor plate from an upper surface of the conductor plate, and
the upper die has a protrusion which contacts with the pressing portion.
